(19) United States
(12) Patent Application Publication
(10) Pub. No.: US 2013/0341491 A1
(43) Pub. Date: Dec. 26, 2013

(54) SOLID-STATE IMAGING DEVICE

(71) Applicant: Panasonic Corporation, Osaka (JP)

(72) Inventors: Yutaka HIROSE, Kyoto (JP); Ryohei MIYAGAWA, Kyoto (JP); Tetsuya UEDA, Toyama (JP); Yoshihisa KATO, Shiga (JP)

(73) Assignee: Panasonic Corporation, Osaka (JP)

(21) Appl. No.: 14/010,641

(22) Filed: Aug. 27, 2013

Related U.S. Application Data
(63) Continuation of application No. PCT/JP2012/000768, filed on Feb. 6, 2012.

(30) Foreign Application Priority Data
Mar. 1, 2011 (JP) 2011-044487

(51) Int. Cl. H01L 27/146

(52) U.S. Cl. CPC H01L 27/14638
USPC 250/208.1; 438/80

(57) ABSTRACT

A solid-state imaging device includes: a substrate; a plurality of first electrodes arranged in a matrix above the substrate, and electrically isolated from each other; an insulator layer covering the first electrodes, having a planarized upper surface, and comprising an insulator; a photoelectric conversion film which is formed above the insulator layer, and converts light into signal charges; a second electrode formed above the photoelectric conversion film; and a signal readout circuit which is formed on the substrate, and generates a readout signal by detecting an amount of current change or voltage change caused by the signal charges at each of the first electrodes, in which the insulator layer allows conduction of at least electrons or holes by quantum mechanical tunneling.

### CROSS REFERENCE TO RELATED APPLICATION

This is a continuation application of PCT International Application No. PCT/JP2012/000768 filed on Feb. 6, 2012, designating the United States of America, which is based on and claims priority of Japanese Patent Application No. 2011-044487 filed on Mar. 1, 2011. The entire disclosures of the above-identified applications, including the specifications, drawings and claims are incorporated herein by reference in their entirety.

### FIELD

The present disclosure relates to a solid-state imaging device for providing an image as an electrical signal,

### BACKGROUND

Each of a complementary metal oxide semiconductor (CMOS) area image sensor and a metal oxide semiconductor (MOS) area image sensor (hereinafter, both referred to as the COMS image sensor) and a charge coupled device (CCD) area image sensor (hereinafter, referred to as the CCD image sensor) generates an image signal by converting an input optical image into an electrical signal. These image sensors are used as a functional element in various imaging apparatuses such as a digital still camera, a digital video camera, a network camera, and a mobile camera.

A conventional image sensor includes pixels arranged in a two-dimensional matrix and each having a photoelectric conversion unit (a photodiode) and a readout circuit unit, in a top surface of a semiconductor substrate. Accordingly, at a light-incoming surface, the area for the photoelectric conversion unit decreases by the area for the readout circuit unit. Thus, the conventional image sensor has a disadvantage that the aperture ratio decreases.

In order to solve this problem, Patent Literature (PTL) 1 discloses a layered sensor having a photoelectric conversion unit including light absorbing materials stacked on a substrate and a readout circuit formed on the substrate.

For each of the pixels, the layered sensor disclosed in PTL 1 has the photoelectric conversion unit including a pixel electrode, a photoelectric conversion film including organic materials stacked above the pixel electrode (on the light incoming side), and an opposite electrode formed on the upper surface of the photoelectric conversion film. The layered sensor also has a charge blocking layer for bring out, from the photoelectric conversion unit as a current signal, positive or negative charges generated by the incident light. This charge blocking layer conducts signal charges and blocks the opposite charges. This charge blocking layer is also formed opposite or on the pixel electrode. In such a structure of the photoelectric conversion unit, the charge blocking layer and the organic photoelectric conversion film on the pixel electrode have defects caused by edge steps and stress concentration at the corners of the pixel electrode. Accordingly, the layered sensor disclosed in PTL 1 has a serious practical problem that a large noise signal is generated.

PTL 2 discloses a technique to solve this problem. According to PTL 2, the charge blocking layer includes a mixture of several types of metal oxides. Furthermore, a low film-forming temperature (0 degrees) is used to form the charge blocking layer that is present as an amorphous phase.

### CITATION LIST

### Patent Literature

[PTL1] Japanese Patent No. 4444371
[PTL2] Japanese Unexamined Patent Application Publication No. 2009-272528

### SUMMARY

### Technical Problem

However, a charge blocking film formed in such a manner is extremely unstable in terms of physical aspect as well as chemical aspect. In other words, the film is formed at extremely low temperatures before high-temperature processes such as annealing and reflow, which causes a serious practical problem that (i) polycrystalline phase is formed and (ii) the chemical composition is changed, after the high-temperature processes.

In view of this, the present disclosure was conceived, and provides a solid-state imaging device which can ensure stability of materials around pixel electrodes and reduce defects in a photoelectric conversion film.

### Solution to Problem

In order to solve such problems of the conventional techniques, a solid-state imaging device according to one embodiment of the present disclosure includes: a substrate; a plurality of first electrodes arranged in a matrix above the substrate, and electrically isolated from each other; an insulator layer covering the first electrodes, having a planarized upper surface, and comprising an insulator; a photoelectric conversion film which is formed above the insulator layer, and converts light into signal charges; a second electrode formed above the photoelectric conversion film; and a signal readout circuit which is formed on the substrate, and generates a readout signal by detecting an amount of current change or voltage change caused by the signal charges at each of the first electrodes, in which the insulator layer allows conduction of at least electrons or holes by quantum mechanical tunneling.

With this, the solid-state imaging device according to one embodiment of the present disclosure can have the planarized insulator layer, thereby reducing defects in the photoelectric conversion film formed on the planarized insulator layer. In addition, the insulator layer can conduct the electrons or the holes generated in the photoelectric conversion film, and thus a current or voltage signal can be detected by the readout circuit provided on the substrate. Furthermore, the solid-state imaging device according to one embodiment of the present disclosure need not include special materials as materials around the first electrode (pixel electrode), and thus the stability of the materials around the first electrode can be ensured.

In addition, the insulator layer above the first electrodes may have a thickness ranging from 0.5 to 15 nm.

With this, the solid-state imaging device according to one embodiment of the present disclosure allows conduction of the electrons or the holes generated in the photoelectric conversion film by quantum mechanical tunneling.

In addition, the insulator layer may have a surface roughness of 1 nm or less.

With this, in the solid-state imaging device according to one embodiment of the present disclosure, the probability of tunneling is constant anywhere in the insulator layer formed on the first electrodes.

In addition, the insulator layer may include at least one of a silicon oxide, an aluminum oxide, a titanium oxide, and a silicon nitride.

With this, in the solid-state imaging device according to one embodiment of the present disclosure, the first electrodes can be covered with an insulator in a simple way. Furthermore, the insulator can be thinned and planarized to allow the tunneling conduction.

In addition, the insulator layer may include an oxide of a metal included in the first electrodes.

With this, in the solid-state imaging device according to one embodiment of the present disclosure, an insulating separator film for isolating pixels can be formed based on the first electrodes themselves, thereby reducing material costs and simplifying the process.

In addition, each of the first electrodes may have a thickness of 15 nm or less.

With this, in the solid-state imaging device according to one embodiment of the present disclosure, when the insulator layer is stacked on the first electrodes formed by patterning an electrode layer, a height of a step in the insulator layer caused by the step of the first electrode can be 15 nm or less in a global region (150 nm). Furthermore, a height of a local step produced around the corner of the first electrode can be substantially 1 nm or less by planarizing the insulator layer to have a thickness of about 2 nm. As a result, the solid-state imaging device can eliminate the defect in the photoelectric conversion film caused by the step at the corner of the electrode. Accordingly, the solid-state imaging device can reduce leakage current and dark current, thereby generating and providing a high-quality image signal.

In addition, the solid-state imaging device may further include a potential supply layer which is formed below a space between adjacent ones of the first electrodes and between the adjacent first electrodes and the substrate, and is able to be set at an electrical potential independent of the adjacent first electrodes.

In addition, the solid-state imaging device may provide, to the potential supply layer, the electrical potential for excluding the signal charges when the photoelectric conversion film converts the light into the signal charges and when the signal readout circuit generates the readout signal.

With this, the solid-state imaging device according to one embodiment of the present disclosure can prevent charge leakage between the pixels while maintaining surface flatness of the insulator layer for isolating the pixels. Accordingly, the solid-state imaging device can capture a high-quality image with low color cross-talk.

In addition, the insulator layer may have an electrical property of conducting first type charges which are either the electrons or the holes and blocking second type charges which are different type charges from the first type charges, the second type charges generated in the photoelectric conversion film may be accumulated at an interface of the insulator layer facing to the photoelectric conversion film, and the signal readout circuit may generate the readout signal by detecting an amount of potential change caused by the accumulated second type charges.

With this, the solid-state imaging device according to one embodiment of the present disclosure does not require a signal-charge storage capacitor independently provided to a circuit on the substrate side of the conventional devices. Thus, the solid-state imaging device can simplify and miniaturize the circuit unit. Furthermore, the solid-state imaging device can also eliminate leakage current that could have been generated at the signal-charge storage capacitor.

In addition, the solid-state imaging device may perform an initialization operation which neutralizes the second type charges accumulated at the interface by injecting the first type charges into the interface from each of the first electrodes via the insulator layer after the detecting of the amount of the potential change.

With this, in the solid-state imaging device according to one embodiment of the present disclosure, charges opposite to the signal charges need not be injected from the second-electrode side of the solid-state imaging device. In other words, the solid-state imaging device can reset the signal charges at each pixel without directly driving the second electrode having a large capacity due to the large area electrode, thereby speeding up a reset operation.

In addition, the signal readout circuit may includes: an amplification transistor which has a gate terminal connected to one of the first electrodes, and generates the readout signal by amplifying the amount of the current change or voltage change at the one first electrode; and a reset transistor which is connected to the one first electrode, and provides a reset signal to the one first electrode, and the solid-state imaging device may further includes a feedback amplifier which feeds back the readout signal to the reset signal, and performs, after the initialization operation, a reset operation which gradually turns off the reset transistor using a tapered gate voltage while the feedback amplifier feeds back the readout signal to the reset signal.

With this, in the solid-state imaging device according to one embodiment of the present disclosure, kTC noise caused by turning on the reset transistor in the reset operation can be reduced to 1/10 or less of that of the conventional devices.

In addition, a method of manufacturing the solid-state imaging device according to one embodiment of the present disclosure may include: patterning an electrode layer to form the first electrodes; covering the first electrodes with an insulating film; and planarizing the insulating film by etching back the insulating film to form the insulator layer.

With this, the planarized insulator layer can be formed without exposing the corners of the first electrodes. Thus, the defects in the photoelectric conversion film formed above the insulator layer can be reduced, thereby achieving very low leakage current.

In addition, a method of manufacturing the solid-state imaging device according to one embodiment of the present disclosure may include: patterning an electrode layer to form a plurality of portions of the electrode layer arranged in a matrix above the substrate and electrically isolated from each other; covering the portions of the electrode layer with a first insulating film; planarizing the first insulating film and the portions of the electrode layer by etching back the first insulating film and the portions of the electrode layer at a same time to form a second insulating film and the first electrodes, respectively; and depositing a third insulating film on the second insulating film and the first electrodes to form the insulator layer including the second insulating film and the third insulating film.

With this, the second insulating film having very high insulation quality can be formed in spaces between the first electrodes, thereby improving the insulation quality between the first electrodes. Furthermore, the first electrodes are formed by partially removing the electrode layer before the second insulating film is formed. This reduces a surface roughness of each of the first electrodes caused by volume expansion in an oxidization process. Thus, the first electrodes and the second insulating film for isolating the pixels can have a good surface flatness entirely.

It should be noted that the present disclosure can be implemented as not only such a solid-state imaging device but also a method of driving a solid-state imaging device which includes, as steps, distinctive means included in the solid-state imaging device.

Furthermore, the present disclosure can be also implemented as: a semiconductor integrated circuit (LSI) which implements a part of all of the features of such a solid-state imaging device; and an imaging device (camera) which includes such a solid-state imaging device.

### Advantageous Effects

As described above, the present disclosure can provide a solid-state imaging device which can ensure stability of materials around pixel electrodes and reduce defects in a photoelectric conversion film.

### BRIEF DESCRIPTION OF DRAWINGS

These and other objects, advantages and features of the invention will become apparent from the following description thereof taken in conjunction with the accompanying drawings that illustrate a specific embodiment of the present disclosure.

FIG. 1 illustrates a block diagram showing a configuration of the solid-state imaging device according to an embodiment 1 of the present disclosure.

FIG. 2 illustrates a circuit diagram of a signal readout circuit for one pixel according to the embodiment 1 of the present disclosure.

FIG. 3 illustrates a cross-sectional view of regions for three pixels which include a photoelectric conversion film, according to the embodiment 1 of the present disclosure.

FIG. 4 illustrates an enlarged cross-sectional view of a photoelectric conversion unit including layers from an upper electrode to a potential supply layer, according to the embodiment 1 of the present disclosure.

FIG. 5 illustrates a timing diagram showing time series variations in main signals of the solid-state imaging device according to the embodiment 1 of the present disclosure.

FIG. 6 illustrates a graph in which a dark current level is plotted against a bias voltage for two devices: a conventional solid-state imaging device; and the solid-state imaging device according to the embodiment 1 of the present disclosure.

FIG. 7 illustrates a circuit diagram of a signal readout circuit for one pixel according to an embodiment 2 of the present disclosure.

FIG. 8 illustrates a timing diagram showing time series variations in main signals of the solid-state imaging device according to the embodiment 2 of the present disclosure.

FIG. 9 illustrates a graph in which a dark current level is plotted against a bias voltage for two devices: a conventional solid-state imaging device; and the solid-state imaging device according to the embodiment 2 of the present disclosure.

FIG. 10A illustrates a diagram showing a first method of manufacturing the solid-state imaging device according to an embodiment 3 of the present disclosure.

FIG. 10B illustrates a diagram showing the first method of manufacturing the solid-state imaging device according to the embodiment 3 of the present disclosure.

FIG. 10C illustrates a diagram showing the first method of manufacturing the solid-state imaging device according to the embodiment 3 of the present disclosure.

FIG. 10D illustrates a diagram showing the first method of manufacturing the solid-state imaging device according to the embodiment 3 of the present disclosure.

FIG. 11A illustrates a diagram showing a second method of manufacturing the solid-state imaging device according to the embodiment 3 of the present disclosure.

FIG. 11B illustrates a diagram showing the second method of manufacturing the solid-state imaging device according to the embodiment 3 of the present disclosure.

FIG. 11C illustrates a diagram showing the second method of manufacturing the solid-state imaging device according to the embodiment 3 of the present disclosure.

FIG. 11D illustrates a diagram showing the second method of manufacturing the solid-state imaging device according to the embodiment 3 of the present disclosure.

FIG. 11E illustrates a diagram showing the second method of manufacturing the solid-state imaging device according to the embodiment 3 of the present disclosure.

### DESCRIPTION OF EMBODIMENTS

Hereinafter, the exemplary embodiments of a solid-state imaging device according to the present disclosure are described with reference to the accompanying Drawings. It should be noted that the present disclosure is described with reference to the following embodiments and the accompanying Drawings, which are for illustrative purposes only and not limitation. The numerical values, shapes, constituent elements, the arrangement and connection of the constituent elements, steps, the processing order of the steps etc. shown in the following embodiments are mere examples, and thus do not limit the present disclosure. The present disclosure is limited by only Claims. Thus, among the constituent elements in the following embodiments, constituent elements not recited in any of the independent claims indicating the most generic concept of the present disclosure are not always required to achieve the aim of the present disclosure, but are described as preferable constituent elements,

### Embodiment 1

The solid-state imaging device according to an embodiment 1 of the present disclosure includes a planarized ultrathin insulating film on a pixel electrode in a photoelectric conversion unit. This ultrathin insulating film allows conduction of at least electrons or holes. With this, the solid-state imaging device according to the embodiment 1 of the present disclosure can ensure stability of materials around the pixel electrode and reduce defects in a photoelectric conversion film.

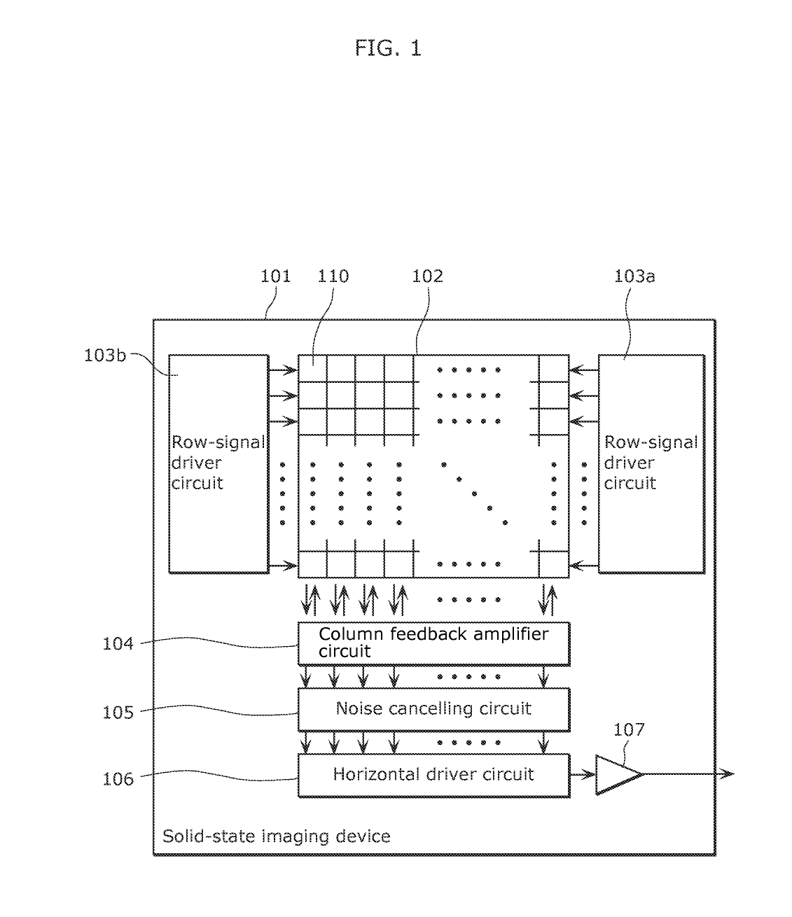

The solid-state imaging device according to the embodiment 1 of the present disclosure is described with reference to FIG. 1 to FIG. 5.

First, an overall configuration of the solid-state imaging device according to the embodiment 1 of the present disclosure is described.

FIG. 1 illustrates a block diagram showing a configuration of the solid-state imaging device 101 according to the embodiment 1 of the present disclosure. This solid-state imaging device 101 includes a pixel array 102, row-signal driver circuits 103a and 103b, a column feedback amplifier circuit 104 in which a circuit having an amplification function and a feedback function is provided for each column, a noise cancelling circuit 105 in which a column amplifier and a noise canceller is provided for each column, a horizontal driver circuit 106, and an output stage amplifier 107. The column feedback amplifier circuit 104 receives an output signal from the pixel array 102 and feeds it back. Thus, the signal flows in both directions, i.e. from and to the pixel array 102 as shown in FIG. 1.

The pixel array 102 includes pixels 110 arranged in a matrix, column signal lines 204 provided for respective columns, and row selection lines provided for respective rows. Each of the column signal lines 204 is connected to pixels 110 arranged along a corresponding one of the columns. Each of the row selection lines is connected to pixels 110 arranged along a corresponding one of the rows.

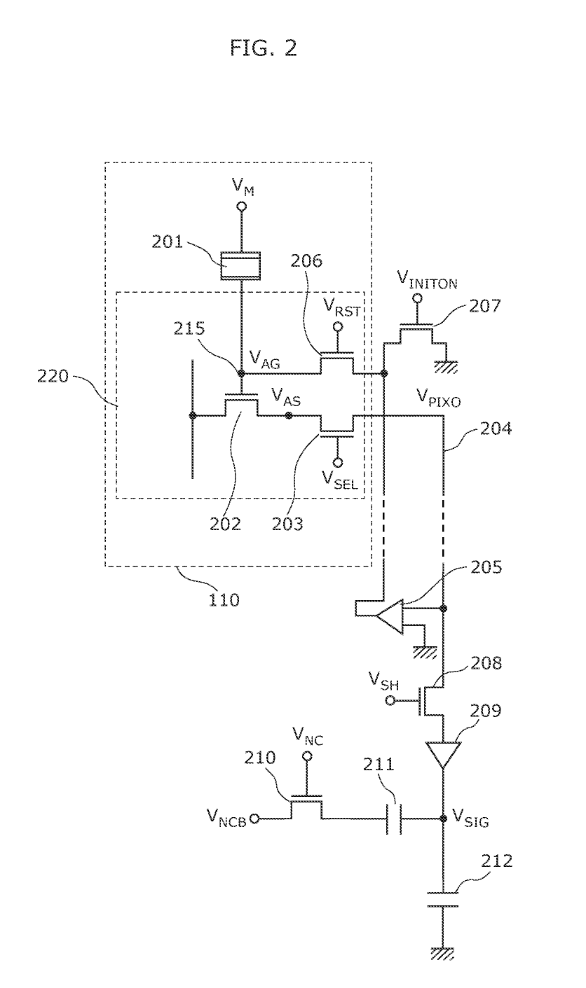

FIG. 2 illustrates a circuit diagram showing a signal readout circuit 220 for one pixel 110 and the peripheral circuitry which are included in the solid-state imaging device 101. As shown in FIG. 2, the pixel 110 includes the photoelectric conversion unit 201 and the signal readout circuit 220. The solid-state imaging device 101 includes, for each column, a column signal line 204, a feedback amplifier 205, an initialization transistor 207, a column selection transistor 208, a column amplifier circuit 209, a transistor 210, and capacitors 211 and 212, which are specifically included in the column feedback amplifier circuit 104, the noise cancelling circuit 105, and the like.

The photoelectric conversion unit 201 generates signal charges corresponding to an amount of incident light by converting incoming photons into electrons.

The signal readout circuit 220 generates a readout signal corresponding to the signal charges generated in the photoelectric conversion unit 201. The signal readout circuit 220 includes an amplification transistor 202, a selection transistor 203, a reset transistor 206, and a FD unit (floating diffusion unit) 215.

The amplification transistor 202 detects the amount of the signal charges generated in the photoelectric conversion unit 201.

The selection transistor 203 controls whether or not to transmit the signal detected by the amplification transistor 202 to the column signal line 204.

The reset transistor 206 provides to the FD unit 215 a reset signal for resetting the photoelectric conversion unit 201 and the FD unit 215.

The feedback amplifier 205 feeds back the readout signal to the reset signal. Specifically, the reset transistor 206 is turned on when the photoelectric conversion unit 201 is reset. At this time, the feedback amplifier 205 feeds back a signal obtained by giving a needed gain to an output signal of the selection transistor 203 to cancel noise at an input stage of the amplification transistor 202.

The initialization transistor 207 controls whether or not to apply a ground potential (hereinafter, referred to as GND) to the photoelectric conversion unit 201 via the reset transistor 206.

The column selection transistor 208 controls whether or not to transmit a pixel output signal V_{PIXO} to an input terminal of the column amplifier circuit 209.

The transistor 210 and the capacitors 211 and 212 are connected in series. The transistor 210 controls whether or not to apply a bias voltage V_{NCB} to the capacitor 211.

The signal amplified by the column amplifier circuit 209 is provided to a difference circuit including the transistor 210 and the capacitors 211 and 212. The difference circuit detects a voltage corresponding to the signal by a difference operation.

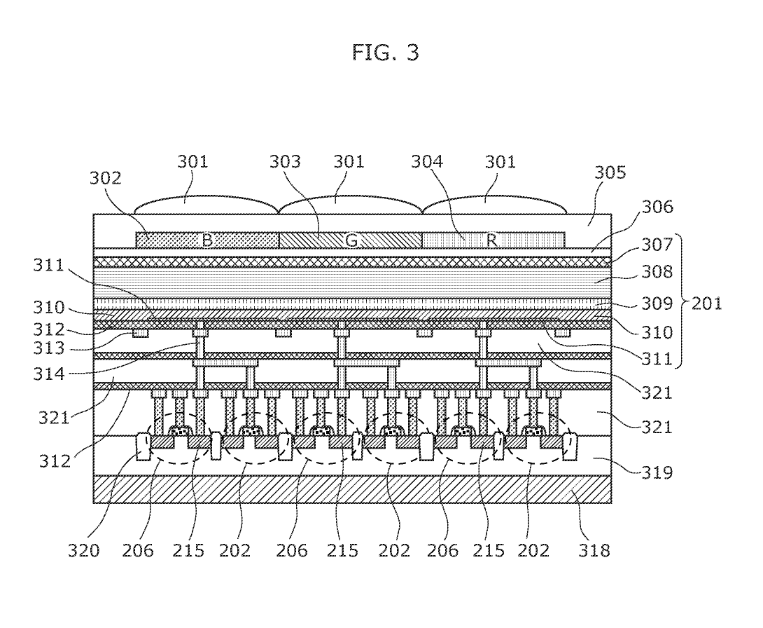

FIG. 3 illustrates a cross-sectional view of regions for three pixels in the solid-state imaging device 101. It should be noted that 10 million pixels 110 are arranged in the actual pixel array 102 for example.

As shown in FIG. 3, the solid-state imaging device 101 includes microlenses 301, a red color filter 302, a green color filter 303, a blue color filter 304, a protective film 305, a flattened film 306, an upper electrode 307 (second electrode), the photoelectric conversion film 308, an electron blocking film 309, the ultrathin insulating film 310, lower electrodes (first electrodes) 311, an insulating film 312, a potential supply layer 313, a wiring layer 314, a substrate 318, a well 319, a shallow trench isolation region (STI region) 320, and an interlayer insulating layer 321.

The substrate 318 is a semiconductor substrate, for example, a silicon substrate.

In order to efficiently collect incident light, the microlens 301 is formed on the top surface of the solid-state imaging device 101 for each pixel 110.

The red color filter 302, the green color filter 303 and the blue color filter 304 are formed to capture a color image. Each of the red color filter 302, the green color filter 303 and the blue color filter 304 is formed below a corresponding one of the microlenses 301 and in the protective film 305. These optical elements are formed on the flattened film 306 to allow the microlenses 301 and the color filters to collect light uniformly and be colored uniformly over the 10 million pixels, respectively. The flattened film 306 comprises SiN for example.

The upper electrode 307 is formed below the flattened film 306 over the entire pixel array 102. The upper electrode 307 is transmissive to visible light. For example, the upper electrode 307 comprises an indium tin oxide (ITO).

The photoelectric conversion film 308 converts light into the signal charges. Specifically, the photoelectric conversion film 308 is formed below the upper electrode 307 and comprises organic molecules highly capable of absorbing light. The photoelectric conversion film has a thickness of 500 nm for example. The photoelectric conversion film 308 is formed by a vacuum deposition process. The organic molecules are highly capable of absorbing light throughout the entire visible spectrum ranging from 400 to 700 nm.

The electron blocking film 309 is formed below the photoelectric conversion film 308 and prevents electronic injection from the lower electrodes 311 while conducting the holes generated by converting incoming photons. This electron blocking film 309 is formed on the ultrathin insulating film 310 having a high flatness.

The ultrathin insulating film 310 corresponds to the insulator layer according to the present disclosure. The ultrathin insulating film 310 is planarized while covering the lower electrodes 311 entirely. Although the ultrathin insulating film 310 comprises an insulator, the thickness of the ultrathin insulating film 310 is ultra-thin. Accordingly, the ultrathin insulating film 310 allows conduction of at least electrons or holes by quantum mechanical tunneling.

The lower electrodes 311 are arranged in a matrix above the substrate 318. The lower electrodes 311 are also electrically isolated with each other. Specifically, the lower electrodes 311 are formed in the ultrathin insulating film 310 and collects the holes generated in the photoelectric conversion film 308. The lower electrodes 311 comprise TiN for example. The lower electrodes 311 are also formed on the flattened insulating film 312 having a thickness of 100 nm.

The lower electrodes 311 are also isolated with each other at 0.2-μm intervals. Then, the ultrathin insulating film 310 is embedded in this isolation region.

The potential supply layer 313 is provided below this isolation region and under the insulating film 312. This potential supply layer 313 comprises Cu for example. Specifically, the potential supply layer 313 is formed below a space between adjacent ones of the lower electrodes 311 and between the adjacent first electrodes 311 and the substrate 318. The potential supply layer 313 is also able to be set at an electrical potential independent of the adjacent lower electrodes 311. Specifically, the electrical potential for excluding the signal charges is provided to the potential supply layer 313 when the photoelectric conversion film 308 converts the light into the signal charges and when the signal readout circuit 220 generates the readout signal. For example, a positive voltage is applied when the signal charges are holes. This can prevent the holes from being mixed into each pixel from the adjacent pixel. It should be noted that such an application of the voltage is controlled by a control unit (not shown) included in the solid-state imaging device 101 for example.

The wiring layer 314 is connected to the potential supply layer 313. The wiring layer 314 is also connected to the FD unit 215 and a gate terminal of the amplification transistor 202. The FD unit 215 is electrically connected to a source terminal of the reset transistor 206. The source terminal of the reset transistor 206 and the FD unit 215 share a diffusion region. These transistors, the selection transistor 203 formed in the same pixel (not shown), and the FD unit 215 are all formed in the same P-type well 319. This well 319 is formed on the substrate 318. In other words, the signal readout circuit 220 as shown in FIG. 2 is formed on the substrate 318 and generates the readout signal corresponding to the signal charges by detecting an amount of current or voltage change at each of the lower electrodes 311. The amplification transistor 202 generates the readout signal by amplifying the current or voltage change at each lower electrode 311.

Each transistor is electrically isolated by the STI region 320 comprising SiO₂.

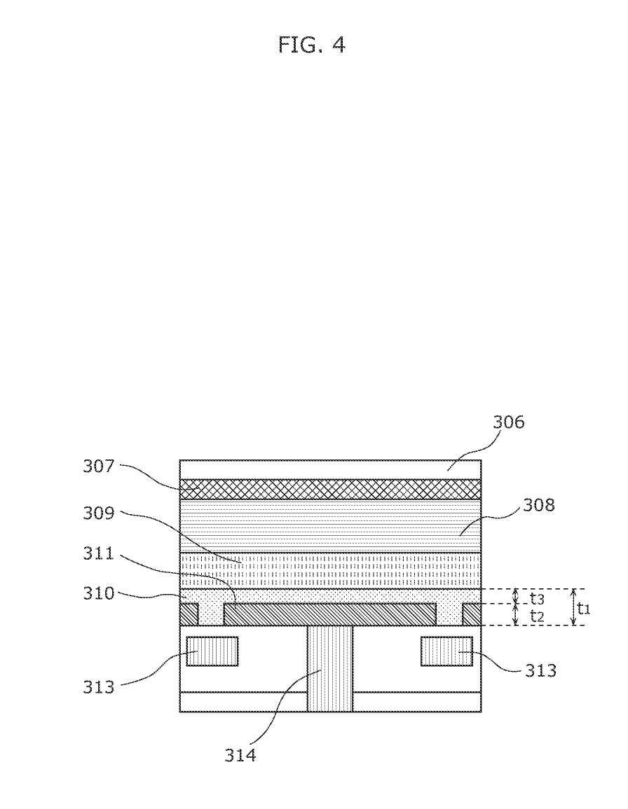

FIG. 4 illustrates an enlarged cross-sectional view of the photoelectric conversion unit 201 including layers from an upper electrode 307 to a potential supply layer 313.

The ultrathin insulating film 310 comprises SiO₂ for example. Total thickness t₁ of the ultrathin insulating film 310 is 2 nm thicker than the thickness t₂ of the lower electrode 311 (=15 nm). Accordingly, the thickness t₃ of the ultrathin insulating film 310 above the lower electrode 311 is 2 nm. With this, the holes generated in the photoelectric conversion film 308 can be efficiently collected at the lower electrodes 311 by quantum mechanical tunneling by applying a positive bias voltage to the upper electrode 307.

It should be noted that the thickness t₃ of the ultrathin insulating film 310 should be a thickness sufficient to allow conduction of the electrons or holes generated in the photoelectric conversion film 308 by quantum mechanical tunneling. For example, the thickness t₃ of the ultrathin insulating film 310 should range from 0.5 nm to 15 nm.

Furthermore, it is preferable that the thickness t₂ of the lower electrode 311 be 15 nm or less.

With this, when the ultrathin insulating film 310 is stacked on the lower electrodes formed by patterning an electrode layer, a height of a step of the ultrathin insulating film 310 produced by the step of the lower electrode 311 can be 15 nm or less in a global region (150 nm). Furthermore, a height of a local step produced around the corner of the lower electrode 311 can be substantially 1 nm or less by planarizing the ultrathin insulating film 310 to have a thickness of about 2 nm. As a result, the solid-state imaging device 101 can eliminate the defect in the photoelectric conversion film 308 caused by the step at the corner of the electrode. Accordingly, the solid-state imaging device 101 can reduce leakage current and dark current, thereby generating and providing a high-quality image signal.

An interface between the ultrathin insulating film 310 and the electron blocking film 309 is planarized. For example, the ultrathin insulating film 310 has a high flatness represented as an rms value of 0.5 nm. As a result, the electron blocking film 309 and the photoelectric conversion film 308 do not have the defects caused by the steps of the corners of the lower electrodes 311 which are problems in the conventional devices. With this, the solid-state imaging device 101 can reduce the leakage current caused by these defects.

It should be noted that it is preferable that the ultrathin insulating film 310 have a surface roughness of 1 nm or less to achieve such an effect. Furthermore, such a structure allows the probability of tunneling to be constant anywhere in the insulator layer 310 formed on the first electrodes 311.

In addition, although an example of the ultrathin insulating film 310 comprising SiO₂ has been described above, the ultrathin insulating film 310 may comprise another highly-insulating material whose film thickness is controllable. For example, the ultrathin insulating film 310 may comprise an aluminum oxide, a titanium oxide, a silicon nitride, or any compound of them. With this, it can be ensured that the lower electrodes 311 are covered with the insulator. Furthermore, the insulator can be thinned and planarized to allow the tunneling conduction.

The ultrathin insulating film 310 may include an oxide of a metal included in the lower electrodes 311. For example, the lower electrodes 311 may include TIN, and the ultrathin insulating film 310 may include a titanium oxide. With this, the insulating separator film for isolating pixels (the ultrathin insulating film 310) can be formed based on the lower electrodes 311 themselves, thereby reducing material costs and simplifying the process.

Hereinafter, the operation of the solid-state imaging device 101 is described. It should be noted that the following control signal is generated by the control unit (not shown) included in the solid-state imaging device 101 for example.

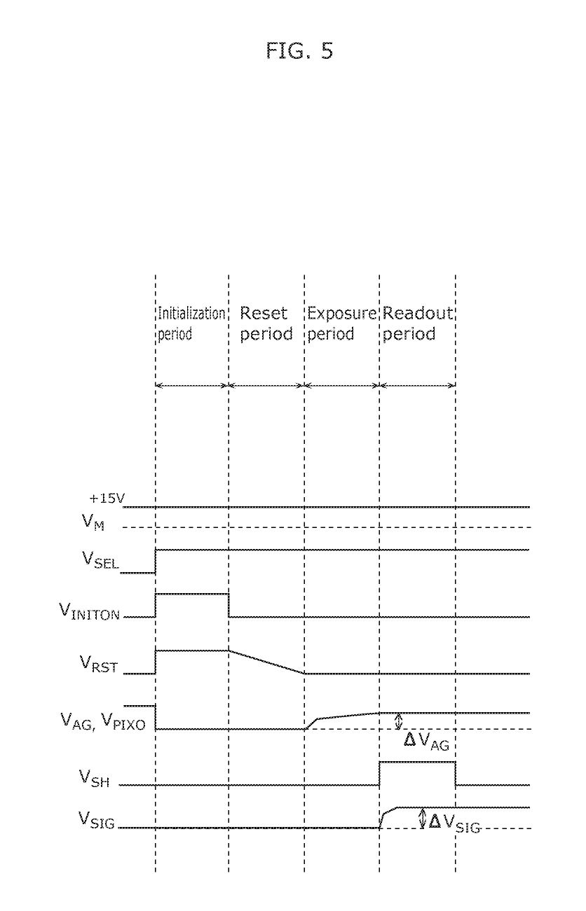

FIG. 5 illustrates a timing diagram showing voltages of respective nodes as shown in FIG. 2. Specifically, FIG. 5 shows the voltages along a route from the photoelectric conversion unit 201 to an output terminal of the column amplifier circuit 209.

An imaging operation includes four different operational mode periods: (1) initialization; (2) reset; (3) exposure; and (4) readout.

During all of the periods, a constant voltage V_{M} (=15 V) is applied to the upper electrode 307. With this, only an output signal for each of the photoelectric conversion units 201, i.e. a potential V_{AG} on the lower-electrode 311 side, should be detected as a signal output. The following describes the operation in each period.

First, in an initialization period, the operation is initiated and each node is reset. Upon starting the initialization period, the selection transistor 203, the reset transistor 206, and the initialization transistor 207 are turned on by raising the gate voltage V_{SEL}, the gate voltage V_{RST}, and the gate voltage V_{INITON} to a High level, respectively. With this, an initialization voltage V_{M} is correctly applied to the photoelectric conversion unit 201, and an input voltage V_{AG} of the amplification transistor 202 is also correctly set to a voltage provided from the reset transistor 206 (GND in the embodiment 1).

Next, in a reset period, the solid-state imaging device 101 performs a reset operation which gradually turns off the reset transistor 206 using a tapered gate voltage while the feedback amplifier 205 feeds back the readout signal to the reset signal. Specifically, the initialization transistor 207 is turned off by dropping the gate voltage V_{INITON} to a Low level. Subsequently, the gate voltage V_{RST} of the reset transistor 206 is gradually dropped to the Low level in at least 1 μsec to have a tapered form. This tapered reset operation completely eliminates noise of the reset transistor 206 which has a feedback connection via the feedback amplifier 205.

Next, in an exposure period, the signal charges generated by converting incoming photons into electrons are accumulated in the FD unit 215 from the moment the reset transistor 206 is completely off. As a result, the voltage V_{AG} increases, and a signal voltage V_{PIXO} also increases accordingly.

In a readout period, after the end of the exposure period, an input voltage V_{SH} of the column selection transistor 208 is raised to the High level to provide the signal voltage V_{PIXO} to the column amplifier circuit 209. With this, a voltage V_{SIG} represents an amount of voltage change ΔV_{SIG} corresponding to an amount of change ΔV_{AG} in signal voltage V_{PIXO}. Thus, the incident light information is read out as the amount of voltage change ΔV_{SIG}.

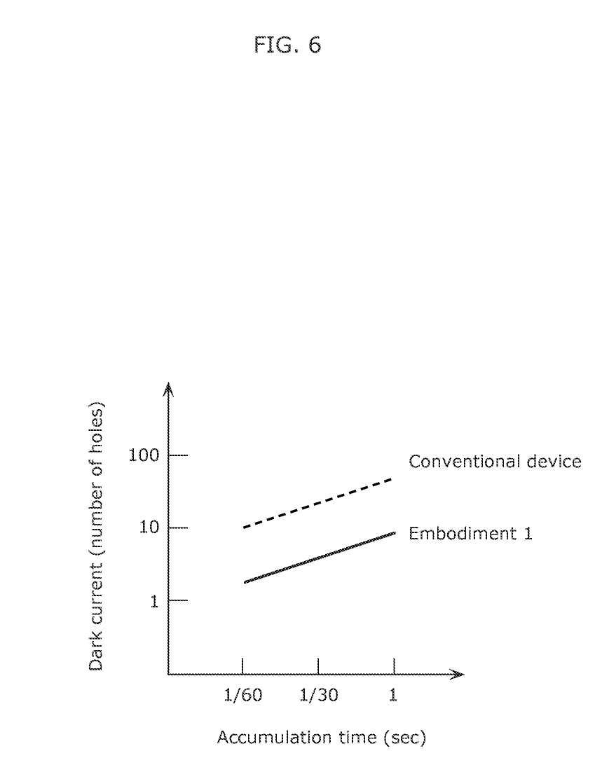

In the solid-state imaging device 101 according to the embodiment 1, defect density around the pixel electrode can be reduced to 1/10 of that of an element having conventional structure pixels. Accordingly, the solid-state imaging device 101 can significantly improve the dark current (the number of holes) per a pixel as shown in FIG. 6. It should be noted that, in FIG. 6, although the dark currents of both devices increase with an increase in an accumulation time, the dark current of the solid-state imaging device 101 according to the embodiment 1 can be significantly reduced to ⅙ of the dark current of the conventional device.

As described above, the solid-state imaging device 101 according to the embodiment 1 of the present disclosure can prevent the defects caused by the steps and the corners of the lower electrodes 311. With this, the solid-state imaging device 101 can ensure the stability of the materials around the electrodes, thereby reducing the leakage current caused by the defects.

Furthermore, the solid-state imaging device 101 according to the embodiment 1 of the present disclosure eliminates the signal charges by injecting the charges opposite to the signal charges from the electrodes, thereby achieving the simplification of a base circuit and the reduction of the leakage current.

Moreover, after eliminating the signal charges in the photoelectric conversion unit 201, the solid-state imaging device 101 gradually turns off the reset transistor 206 while providing feedback to the reset transistor 206. With this, the solid-state imaging device 101 can achieve a new effect of eliminating the charges in the photoelectric conversion unit 201 without kTC noise (reset noise).

### Embodiment 2

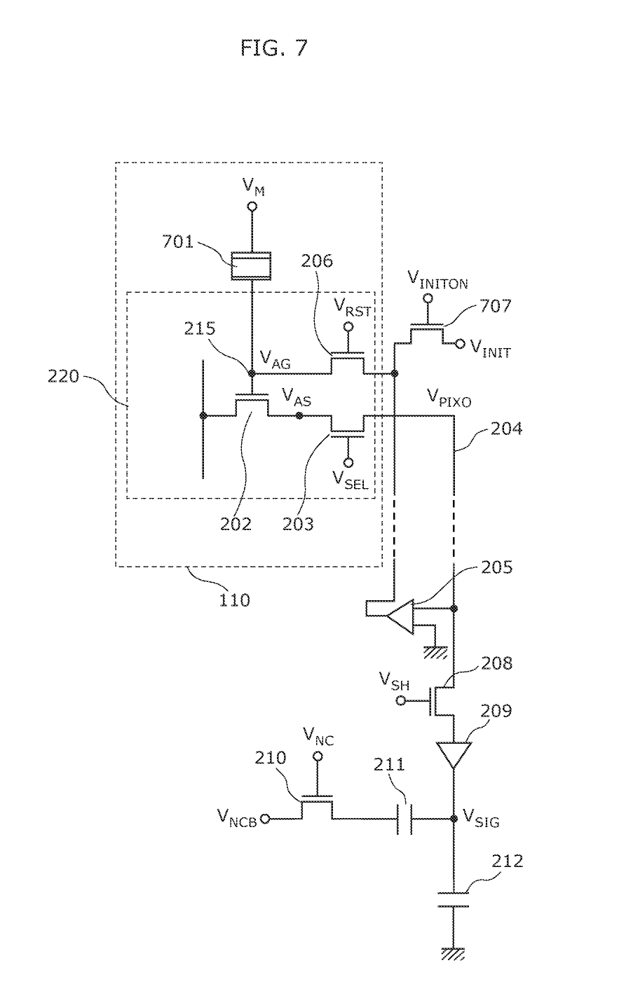

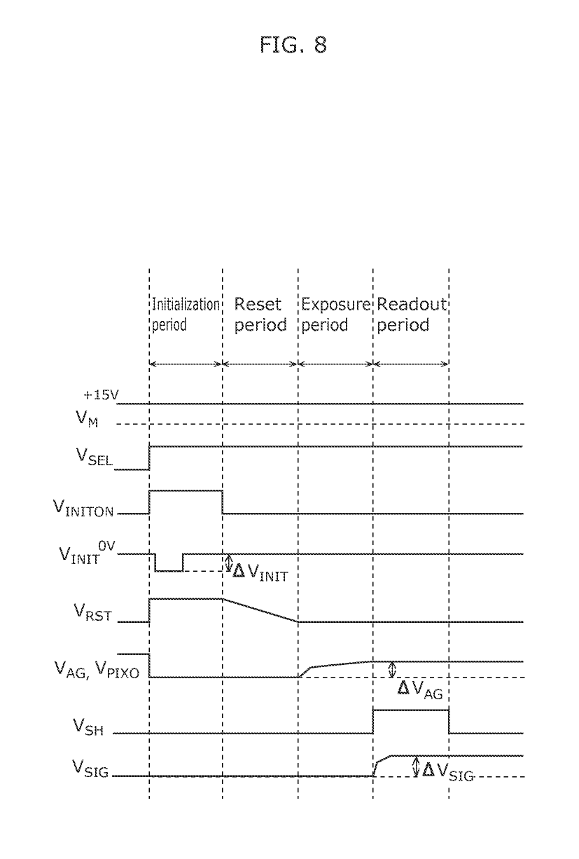

Next, an embodiment 2 according to the present disclosure is described with reference to FIG. 7 and FIG. 8. It should be noted that a block diagram of the solid-state imaging device 101 according to the embodiment 2 is the same as FIG. 1 shown in the embodiment 1.

It should be noted that the following mainly describes differences from the embodiment 1 and thus a detailed description of the same is omitted. In each of the drawings, an element identical to that in the embodiment 1 is numbered the same.

FIG. 7 illustrates a circuit diagram showing a signal readout circuit 220 for one pixel and the peripheral circuitry which are included in the solid-state imaging device 101 according to the embodiment 2 of the present disclosure.

The solid-state imaging device 101 according to the embodiment 2 of the present disclosure is different in structure of the photoelectric conversion unit 701 from that according to the embodiment 1, and also different in that a bias voltage V_{INIT} is applied to the initialization transistor 707.

The photoelectric conversion unit 701 generates charges corresponding to an amount of incident light, and has a function of temporarily storing the generated charges.

The initialization transistor 707 controls whether or not to apply a bias voltage V_{INIT} to the photoelectric conversion unit 701 via the reset transistor 206.

The structure of the photoelectric conversion unit 701 is basically the same as the structure shown in FIG. 3 and FIG. 4. However, the thickness t₃ of the ultrathin insulating film 310 above the lower electrode 311 is thicker than that in the embodiment 1. For example, the thickness t₃ is 5 nm. With this, the ultrathin insulating film 310 has an electrical property of conducting first type charges which are either the electrons or the holes, and blocking second type charges which are different type charges from the first type charges. Thus, the second type charges generated in the photoelectric conversion film 308 are accumulated at the interface of the ultrathin insulating film 310 facing to the photoelectric conversion film 308. The signal readout circuit 220 generates the readout signal by detecting an amount of potential change caused by the accumulated second type charges.

Specifically, the holes generated in the photoelectric conversion film 308 move to the lower-electrode 311 side by applying the bias voltage to the upper electrode 307. However, as described above, the ultrathin insulating film 310 according to the embodiment 2 has a thickness of 5 nm above the lower electrode 311, and this thickness is thicker than that in the embodiment 1. With this, the normal bias voltage (15 to 20 V) applied to the lower electrode 311 fails to allow conduction of the generated holes by quantum mechanical tunneling, and the generated holes are accumulated at the interface between the electron blocking film 309 and the ultrathin insulating film 310. An output signal of the photoelectric conversion unit 701, i.e. the potential of the lower electrode 311, varies depending on the accumulation of charges of holes proportional to the incident light. The signal readout circuit 220 reads out an amount of this potential change as the readout signal.

With this, the solid-state imaging device 101 does not require a signal-charge storage capacitor independently provided to a circuit on the substrate side of the conventional devices. Thus, the solid-state imaging device 101 can simplify and miniaturize the circuit unit. Furthermore, the solid-state imaging device 101 can also eliminate leakage current that could have been generated at the signal-charge storage capacitor.

FIG. 8 illustrates a timing diagram showing voltages of respective nodes as shown in FIG. 7. Specifically, FIG. 8 shows the voltages along a route from the photoelectric conversion unit 701 to an output terminal of the column amplifier circuit 209.

An operation shown in FIG. 8 is different in the initialization period from that shown in FIG. 5.

In the initialization period, the operation is initiated and each node is reset. During the initialization period after the detection of the amount of potential change, the solid-state imaging device 101 injects the first type charges from each lower electrode 311 via the ultrathin insulating film 310 into the interface of the ultrathin insulating film 310 facing to the photoelectric conversion film 308. With this, the solid-state imaging device 101 neutralizes the second type charges accumulated at the interface.

Specifically, upon starting the initialization period, the selection transistor 203, the reset transistor 206, and the initialization transistor 207 are turned on by raising the gate voltage V_{SEL}, the gate voltage V_{RST}, and the gate voltage V_{INITON} to a High level, respectively. Next, a negative voltage ΔV_{INIT} is applied as a drain voltage V_{INIT} of the initialization transistor 707. With this, the initialization voltage V_{M}+|ΔV_{INIT}| is correctly applied to the photoelectric conversion unit 701. With this, electrons are injected via the ultrathin insulating film 310 by quantum mechanical tunneling. These electrons neutralize the signal charges of the holes accumulated at the interface between the electron blocking film 309 and the ultrathin insulating film 310 in a preceding frame. Next, the initialization voltage V_{M} is correctly applied to the photoelectric conversion unit 701 and the input voltage V_{AG} of the amplification transistor 202 is correctly set to a voltage (GND) provided from the reset transistor 206 by setting the drain voltage V_{INIT} of the initialization transistor 707 to GND.

With this, in the solid-state imaging device 101, charges opposite to the signal charges need not be injected from the upper-electrode 307 side of the solid-state imaging device 101. In other words, the solid-state imaging device 101 can reset the signal charges at each pixel without directly driving the upper electrode 307 having a large capacity due to the large area electrode, thereby speeding up the reset operation.

It should be noted that the operation following the initialization operation is the same as that in the embodiment 1.

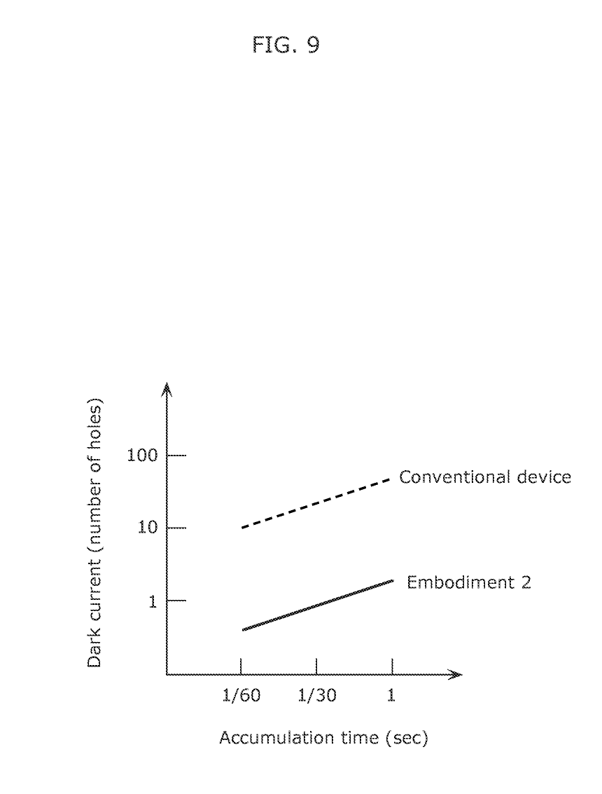

In the solid-state imaging device 101 according to the embodiment 2, the defect density around the pixel electrode can be reduced to 1/20 of that of an element having conventional structure pixels. Accordingly, the solid-state imaging device 101 can significantly improve the dark current (the number of holes) per a pixel as shown in FIG. 9. It should be noted that, in FIG. 9, although the dark currents of both devices increase with an increase in an accumulation time, the dark current of the solid-state imaging device 101 according to the embodiment 2 can be significantly reduced to 1/10 of the dark current of the conventional device.

### Embodiment 3

An embodiment 3 of the present disclosure describes a method of manufacturing the solid-state imaging device 101 according to the foregoing embodiment 1. It should be noted that a method of manufacturing the solid-state imaging device 101 according to the embodiment 2 is the same as that in the embodiment 3.

Firstly, a first manufacturing method is described.

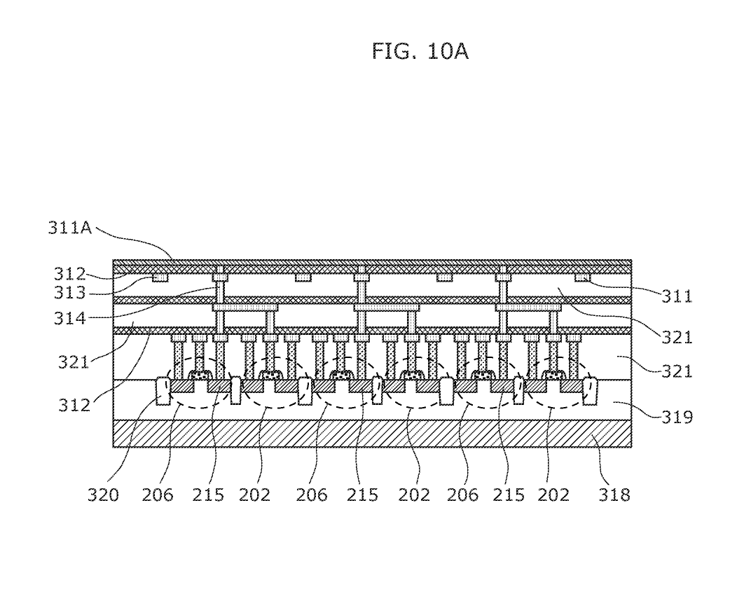

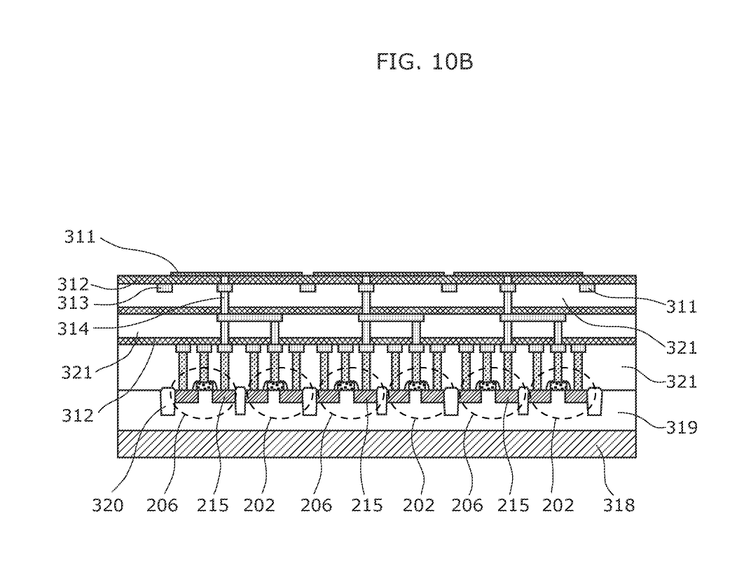

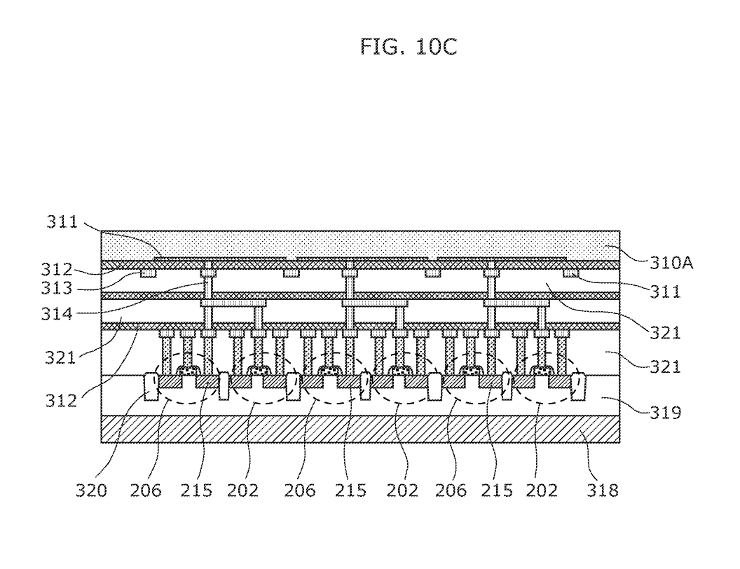

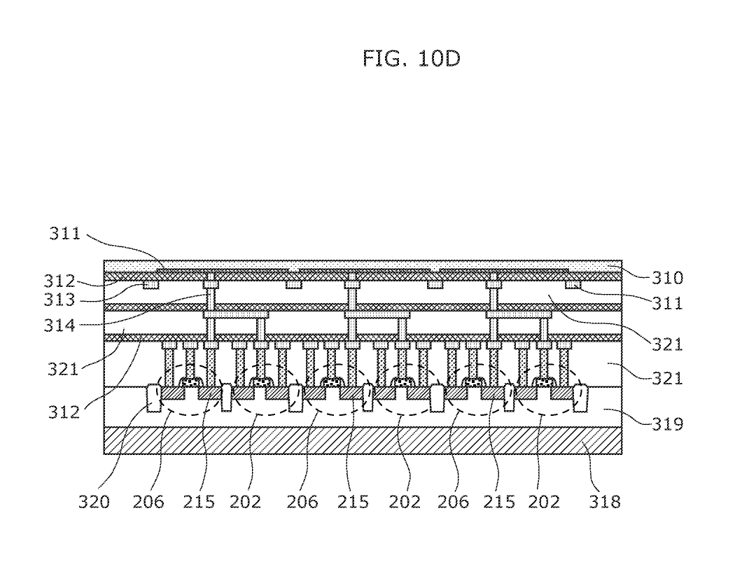

FIG. 10A to FIG. 10D, each of which illustrates a cross-sectional view of the solid-state imaging device 101 in a manufacturing process, show the first manufacturing method until after electrode units of the solid-state imaging device 101 are formed.

First, as shown in FIG. 10A, a fundamental circuit of the solid-state imaging device 101 is formed using a Si-CMOS process. Next, a wiring layer 314 is formed on the fundamental circuit, and a flattened insulating film 312 is formed on the wiring layer 314. Subsequently, an electrode layer 311A for forming lower electrodes 311 comprising TiN is deposited entirely over the flattened insulating film 312.

Next, the electrode layer 311A is patterned into a shape corresponding to the lower-electrode arrangement using a lithography process and a dry-etching process, thereby forming the lower electrodes 311 (FIG. 10B).

Next, an insulating film 310A comprising SiO₂ is deposited to have a thickness sufficiently thicker than the surface step height of the lower electrode 311, thereby covering the lower electrodes 311 with the insulating film 310A (FIG. 10C).

Subsequently, the insulating film 310A is polished to a desired thickness slightly thicker than the thickness of the lower electrode 311 using a Chemical Mechanical Polishing (CMP) process while the thickness of the insulating film 310A is accurately monitored. With this, the final ultrathin insulating film 310 is formed (FIG. 10D). In this manner, the ultra insulating film 310 is formed by planarizing the insulating film 310A using an etch-back process.

After this process, an electron blocking film 309 is formed, and a photoelectric conversion film 308 is formed using a vacuum deposition process. Then, an upper electrode 307 is formed using a sputtering process, and a flattened film 306 is also formed using a sputtering process. Finally, color filters (a red color filter 302, a green color filter 303, and a blue color filter 304) and microlenses 301 are sequentially formed.

Secondly, a second manufacturing method is described.

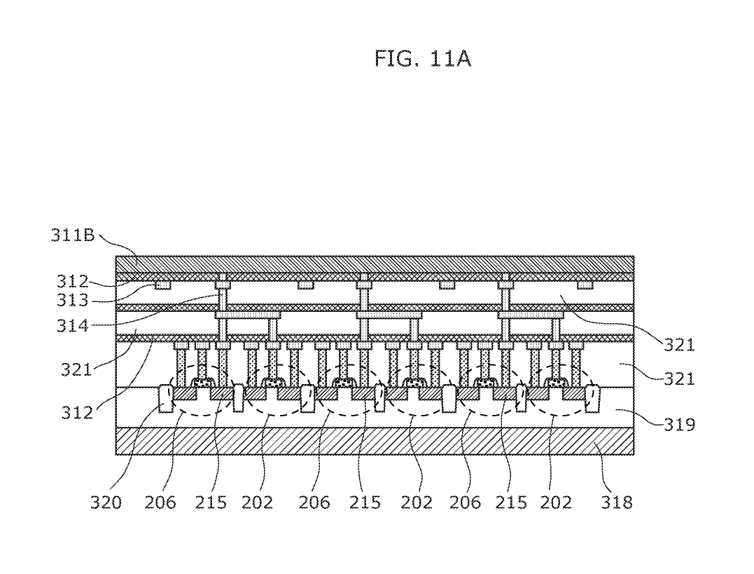

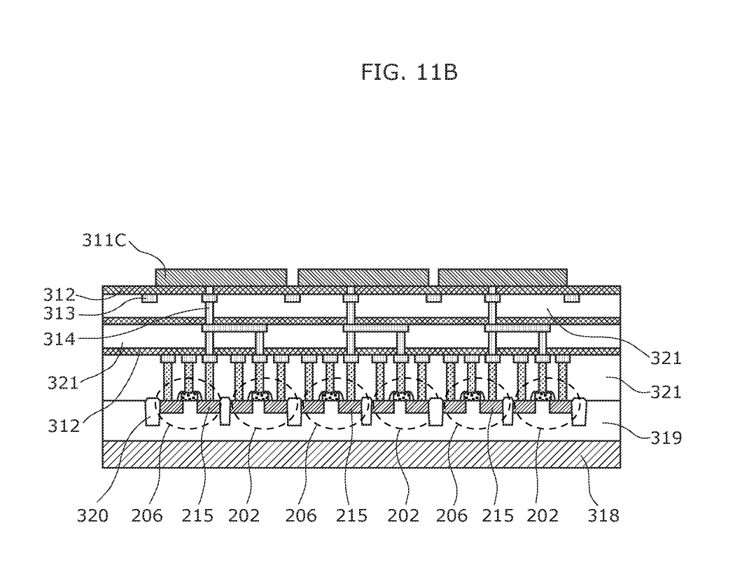

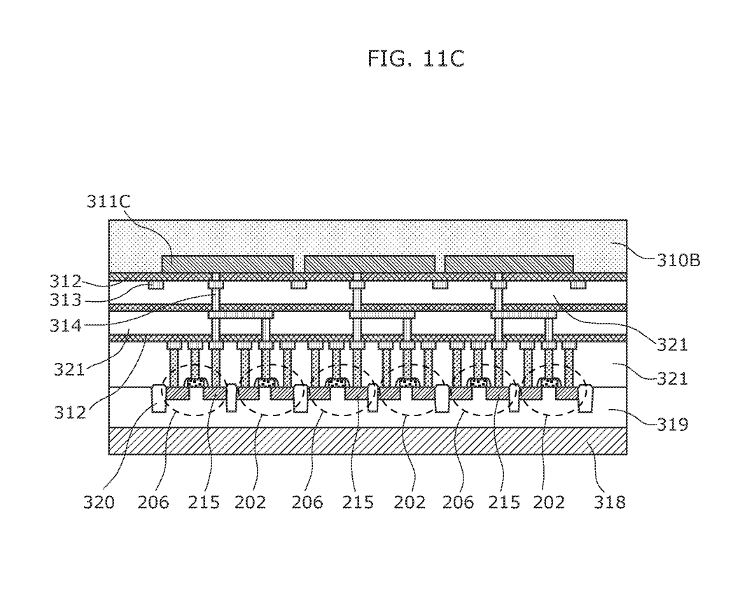

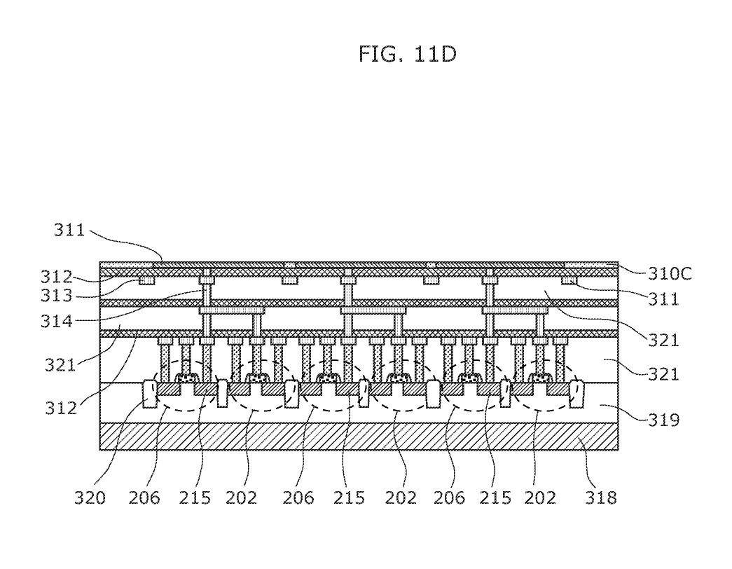

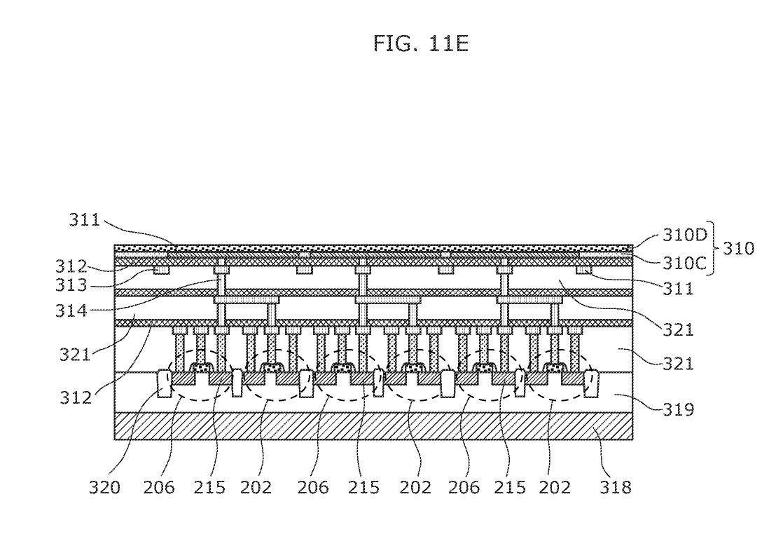

FIG. 11A to FIG. 11E, each of which illustrates a cross-sectional view of the solid-state imaging device 101 in a manufacturing process, show the second manufacturing method until after the electrode unit of the solid-state imaging device 101 is formed.

First, as shown in FIG. 11A, a fundamental circuit, a wiring layer 314, and an insulating film 312 are formed in the same manner as the foregoing first manufacturing method. Subsequently, an electrode layer 3113 for forming lower electrodes 311 comprising TiN is deposited entirely over the insulating film 312. Here, the thickness of the electrode layer 3113 is determined by considering the thickness to be polished in the following CMP process. For example, the electrode layer 311B has a thickness of 25 nm which is thicker than 15 nm.

Next, the electrode layer 3113 is patterned into a shape corresponding to the lower-electrode arrangement using a lithography process and a dry-etching process, thereby forming a plurality of portions of the electrode layer 311C (FIG. 11B). Here, the portions of the electrode layer 311C are arranged in a matrix and electrically isolated with each other.

Next, the insulating film 310B comprising SiO₂ is deposited to have a thickness sufficiently thicker than the surface step height of the patterned electrode layer 311C, thereby covering the patterned electrode layer 311C with the insulating film 310B (FIG. 11C).

Subsequently, the insulating film 310 B and the patterned electrode layer 311C are polished to a desired thickness of the patterned electrode layer 311C using a CMP process while the thickness of the insulating film 310B is accurately monitored. In this manner, the insulating film 310B and the patterned electrode layer 311C are planarized by etching back them at the same time. With this, the insulating film 310C and the lower electrodes 311 are formed (FIG. 11D). In this process, the patterned electrode layer 311C and the insulating film 310B are polished at the same time, so that slight steps are generated. However, these steps can be ignored in most practical cases.

Next, an additional insulating film 310D is deposited on the insulating film 310C and the lower electrodes 311. Specifically, Al₂O₃ is vacuum-deposited using an atomic layer deposition process, thereby forming the additional insulating film 310D. With this, the final ultrathin insulating film 310 including the insulating film 310C and the additional insulating film 310D is formed (FIG. 11E).

After this process, in the same manner as the foregoing first manufacturing method, an electron blocking film 309, a photoelectric conversion film 308, an upper electrode 307, a flattened film 306, color filters (a red color filter 302, a green color filter 303, and a blue color filter 304), and microlenses are sequentially formed.

Thus, the solid-state imaging device according to the embodiments of the present disclosure has been described, but the present disclosure is not limited to these embodiments.

Each processing unit included in the solid-state imaging device according to the foregoing embodiments is typically implemented as a large-scale integration (LSI) circuit, which is an integrated circuit. These may be integrated into separate chips, or some or all of them may be integrated into a single chip.

The integration may be achieved, not only as a LSI, but also as a dedicated circuit or a general purpose processor. Also applicable is a field programmable date array (FPGA), which allows post-manufacture programming, or a reconfigurable processor LSI, which allows post-manufacture reconfiguration of connection and setting of circuit cells therein.

In the foregoing cross-sectional views, the corner and the side of each constituent element are linearly drawn, but the constituent elements including round corners and curved sides in terms of the manufacturing process are also included in the present disclosure.

At least part of functions of the solid-state imaging device and the modifications thereof according to the foregoing embodiments may be combined.

All the figures used above are provided for purposes of illustration of the present disclosure, and the present disclosure is not limited to these figures. The logic levels represented as High/Low levels or the switching sates represented as ON/OFF are provided for purposes of illustration of the present disclosure, and a similar result can be obtained by combining different logic levels or switching states. The n-type and p-type transistors and the like are provided for purposes of illustration of the present disclosure, and a similar result can be obtained by reversing these transistors. All the materials of the foregoing constituent elements are examples for illustrating the present disclosure, and the present disclosure is not limited to these materials. The relation of connection between the constituent elements is an example for illustrating the present disclosure, and the relation of connection for achieving the functions of the present disclosure is not limited to this relation.

In the foregoing description, MOS transistors are used as examples, but other transistors are possible.

Various modifications to the embodiments that can be conceived by those skilled in the art which are within the teachings of the present disclosure may be included in the scope of the present disclosure.

### INDUSTRIAL APPLICABILITY

The present disclosure can be applied to a solid-state imaging device. The present disclosure also can be applied to a monitoring camera, a network camera, a car-mounted camera, a digital camera, a mobile phone, and the like.

1. A solid-state imaging device comprising:
a substrate;
a plurality of first electrodes arranged in a matrix above the substrate, and electrically isolated from each other;
an insulator layer covering the first electrodes, having a planarized upper surface, and comprising an insulator;
a photoelectric conversion film formed above the insulator layer, the photoelectric conversion film converting light into signal charges;
a second electrode formed above the photoelectric conversion film; and
a signal readout circuit formed on the substrate, the signal readout circuit generating a readout signal by detecting an amount of current change or voltage change caused by the signal charges at each of the first electrodes,
wherein the insulator layer allows conduction of at least electrons or holes by quantum mechanical tunneling.

2. The solid-state imaging device according to claim 1,
wherein the insulator layer above the first electrodes has a thickness ranging from 0.5 to 15 nm.

3. The solid-state imaging device according to claim 1,
wherein the insulator layer has a surface roughness of 1 nm or less.

4. The solid-state imaging device according to claim 1,
wherein the insulator layer includes at least one of a silicon oxide, an aluminum oxide, a titanium oxide, and a silicon nitride.

5. The solid-state imaging device according to claim 1,
wherein the insulator layer includes an oxide of a metal included in the first electrodes.

6. The solid-state imaging device according to claim 1,
wherein each of the first electrodes has a thickness of 15 nm or less.

7. The solid-state imaging device according to claim 1 further comprising
a potential supply layer formed below a space between adjacent ones of the first electrodes and between the adjacent first electrodes and the substrate, the potential supply layer being able to be set at an electrical potential independent of the adjacent first electrodes.

8. The solid-state imaging device according to claim 7,
wherein the solid-state imaging device provides, to the potential supply layer, the electrical potential for excluding the signal charges when the photoelectric conversion film converts the light into the signal charges and when the signal readout circuit generates the readout signal.

9. The solid-state imaging device according to claim 7,
wherein the insulator layer has an electrical property of conducting first type charges which are either the electrons or the holes and blocking second type charges which are different type charges from the first type charges,
the second type charges generated in the photoelectric conversion film are accumulated at an interface of the insulator layer facing to the photoelectric conversion film, and
the signal readout circuit generates the readout signal by detecting an amount of potential change caused by the accumulated second type charges.

10. The solid-state imaging device according to claim 9,
wherein the solid-state imaging device performs an initialization operation which neutralizes the second type charges accumulated at the interface by injecting the first type charges into the interface from each of the first electrodes via the insulator layer after the detecting of the amount of the potential change.

11. The solid-state imaging device according to claim 10,
wherein the signal readout circuit includes:
an amplification transistor having a gate terminal connected to one of the first electrodes, the amplification transistor generating the readout signal by amplifying the amount of the current change or voltage change at the one first electrode; and
a reset transistor connected to the one first electrode, the reset transistor providing a reset signal to the one first electrode, and
the solid-state imaging device further comprises a feedback amplifier which feeds back the readout signal to the reset signal, and performs, after the initialization operation, a reset operation which gradually turns off the reset transistor using a tapered gate voltage while the feedback amplifier feeds back the readout signal to the reset signal.

12. A method of manufacturing the solid-state imaging device according to claim 1, the method comprising:
patterning an electrode layer to form the first electrodes;
covering the first electrodes with an insulating film; and
planarizing the insulating film by etching back the insulating film to form the insulator layer.

13. A method of manufacturing the solid-state imaging device according to claim 1, the method comprising:
patterning an electrode layer to form a plurality of portions of the electrode layer arranged in a matrix above the substrate and electrically isolated from each other;
covering the portions of the electrode layer with a first insulating film;
planarizing the first insulating film and the portions of the electrode layer by etching back the first insulating film and the portions of the electrode layer at a same time to form a second insulating film and the first electrodes, respectively; and
depositing a third insulating film on the second insulating film and the first electrodes to form the insulator layer including the second insulating film and the third insulating film.
